(19) United States
(12) Patent Application Publication
(10) Pub. No.: US 2003/0044024 A1
(43) Pub. Date: Mar. 6, 2003

(54) Method and device for processing sound signals

(76) Inventors: Ronaldus Maria Aarts, Eindhoven (NL); Erik Larsen, Urbana, IL (US)

Correspondence Address: Michael E. Marion, c/o U.S. PHILIPS CORPORATION, Intellectual Property Department, 580 White Plains Road, Tarrytown, NY, 10591, US

(21) Appl. No.: 10/228,603

(22) Filed: Aug. 27, 2002

(30) Foreign Application Priority Data
Aug. 31, 2001 (EP) 01203279.3

(51) Int. Cl. H03G 3/00

(52) U.S. Cl. 381/61; 381/63

(57) ABSTRACT

A sound signal is processed in two branches (10, 20).

In first branch (10), the original signal (S_{OR}) is maintained.

In second branch (20), at least a portion (BW1; 63) of the original signal is fed to a non-linear device (22). This portion (BW1) preferably corresponds to the highest octave of the original signal.

Non-linear device (22) produces harmonic frequencies (S_{HAR}) with respect to frequency components received at its input. At least a portion (BW3; 65) of this resulting harmonic signal (S2; BW2; 64) is, optionally after attenuation or amplification, combined with original signal (S_{OR}) from first branch (10), which possibly is delayed by a delay device (11). This combination may be a simple addition.

Said portion (BW3; 65) of resulting signal (S2; BW2; 64) corresponds with a higher frequency portion (BW62) of the original spectrum, or is adjacent to the original spectrum (BW_{OR}) at the high-frequency limit thereof.

The present invention relates in general to the processing of sound signals.

An original sound signal contains signal components within a range of frequencies; this range will hereinafter be referred to as “original bandwidth”. If the original sound signal originates from a natural source, such as speech spoken by a person, or music produced by a musical instrument, the original sound signal will also be referred to as “natural sound” and its bandwidth will also be referred to as “natural bandwidth”.

When natural sound is processed by electronic equipment or the like, for the purpose of communication transfer, recording, etc., the bandwidth of the signal is usually limited with respect to the natural bandwidth. The reason for this may depend on the circumstances. It may be that the signal transfer path is simply not designed for transferring high frequencies (for instance: telephone). It may also be that the signal is deliberately bandlimited in order to reduce the amount of data to be recorded or transferred. For instance, in the case of a spoken book, a data carrier can carry a longer timespan of spoken text. In the case of music, audio may be compressed, like for instance MP3.

In many cases, the loss of information caused by such limitation of bandwidth is neglectable, or at least acceptable. However, it is a well-known problem that the bandlimited signals, in general, sound less natural (for a human observer) than the corresponding original signal with the natural bandwidth (full bandwidth).

Of course, the perception depends on the actual width of the limited frequency band. For instance, in the case of telephony, “narrowband” communication involves a bandwidth of 0.30-3.4 kHz, but it has been established that “wideband” communication is preferred, involving a bandwidth of 0.05-7.0 kHz. Therefore, the state of the art comprises many systems for generating a wideband signal from an original narrowband signal. These known systems suffer from some disadvantages. Many of the known systems are based on Fourier transformation and/or extensive filtering; hence these systems suffer from high computational complexity. Further, these known systems are designed for the processing of speech signals only, and they do not function well for other types of sound. In many cases, the system is a self-learning system, having several parameters that need to be initialized and then adapted in a training period in which the system is trained to predict wideband speech from narrowband speech.

Therefore, a general objective of the present invention is to provide a method and system for processing sound signals, capable of generating a wider band signal from an original input signal, in which the above-mentioned disadvantages are eliminated or at least alleviated.

More particularly, the present invention aims to provide a method and system for processing sound signals, capable of generating a wider band signal from an original input signal, which does not need a training period and can be used for many types of sound signals, for instance music as well as speech.

Further, it is a purpose of the present invention to provide such method and system with reduced complexity, while the system is capable to be implemented in analog implementation as well as in digital implementation.

In order to attain these objectives, the present invention proposes to generate harmonic signals on the basis of at least part of the signal content of the original signal, and to add these harmonic signals to the original signal, possibly after some filtering. In this respect, it is acknowledged that extension of a bass spectrum to lower frequencies by using sub-harmonic frequencies is known per se; however, the present invention seeks to extend a spectrum to higher frequencies, and further the generation of sub-harmonic frequencies involves a technique different from the generation of harmonic frequencies.

These and other aspects, features and advantages of the present invention will be explained in more detail by the following description of a preferred embodiment of a signal processing system according to the present invention, with reference to the drawings, in which:

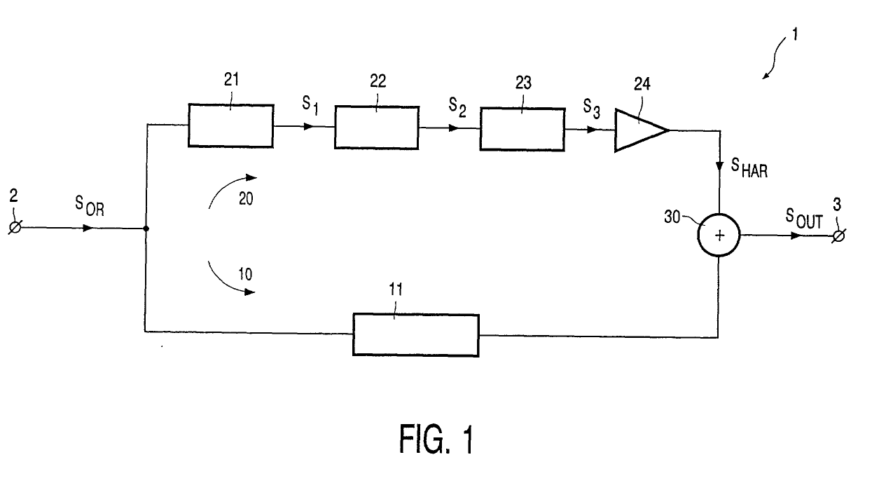

FIG. 1 schematically shows a functional block diagram illustrating the signal processing in accordance with the present invention;

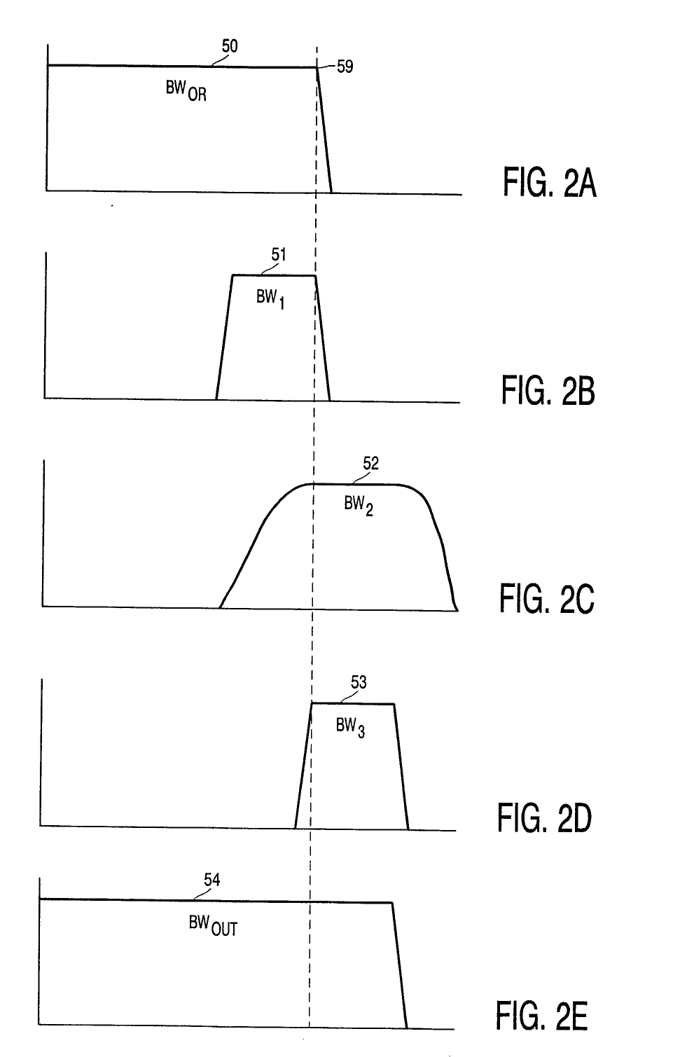

FIGS. 2A-2E schematically illustrate the bandwidths of signals at various stages of the signal processing;

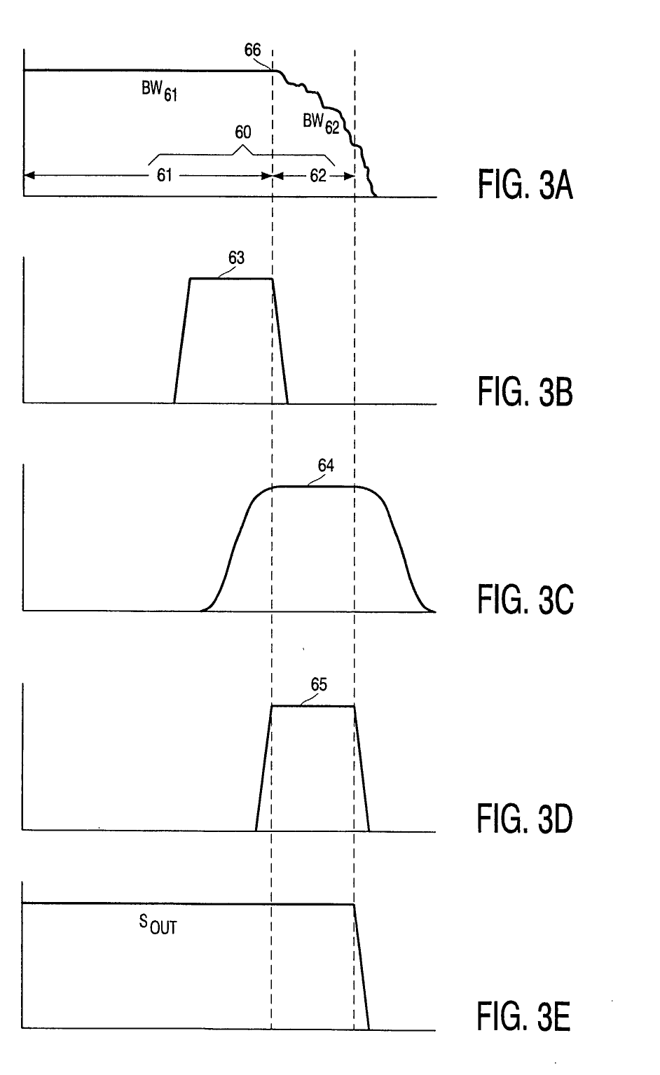

FIGS. 3A-3E schematically illustrate the bandwidths of signals at various stages of the signal processing, for another type of input signal

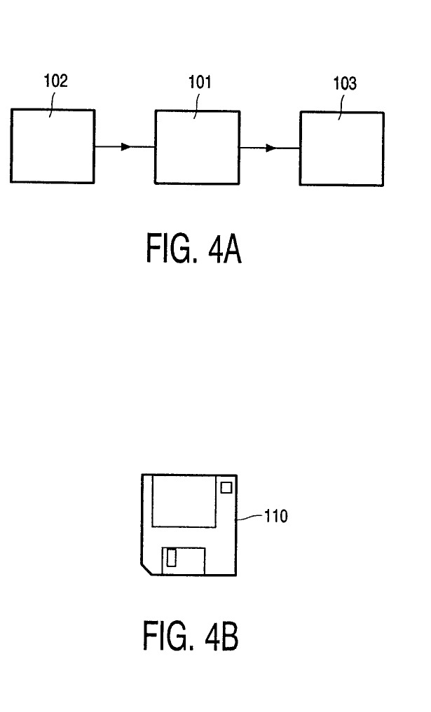

FIG. 4 schematically illustrates an embodiment of an apparatus according to the invention.

FIG. 1 schematically shows a functional block diagram of a signal processing system generally referred to by the reference numeral 1. The system 1 has an input 2 for receiving an original sound signal S_{OR}, and an output 3 for providing an output signal S_{OUT}. The system 1 comprises two signal transfer paths 10 and 20, respectively, between input 2 and output 3.

A first signal transfer path 10 is for transferring the original sound signal S_{OR}; therefore, this first signal transfer path 10 is also referred to as original signal transfer path. Although this original signal transfer path 10 may contain signal processing components for improving the original signal, such is not essential for the present invention and therefore not shown in FIG. 1. On the other hand, the original signal transfer path 10 normally will contain a delay device 11 in order to compensate for delays in the other transfer path 20. Delay devices are known per se, and any suitable known per se delay device may be used to implement delay device 11, as will be clear to a person skilled in the art; therefore, no detailed description of the construction and functioning of such delay device is necessary here.

The second signal transfer path 20 is for generating a harmonic signal S_{HAR} on the basis of the original sound signal S_{OR}; therefore, this second signal transfer path 20 is also referred to as harmonic signal transfer path.

The harmonic signal S_{HAR} is combined with the (optionally delayed) original signal S_{OR} in combiner or adder 30, to generate the output signal S_{OUT}, which may be expressed as S_{OUT}=S_{OR}+S_{HAR}. This output signal S_{OUT} has a spectrum 54 with a bandwidth BW_{OUT} which is extended with respect to the bandwidth BW_{OR} of the original signal S_{OR} Within the bandwidth BW_{OR} of the original signal S_{OR}, the signal components of the output signal S_{OUT} are substantially equal to the signal components of the original signal S_{OR}. In addition, the output signal S_{OUT} also contains signal components in a frequency range beyond the bandwidth BW_{OR} of the original signal S_{OR}, these additional signal components being essentially the components of the harmonic signal S_{HAR} generated in the harmonic signal transfer path.

In the following, the signal processing in the harmonic signal transfer path 20 will be explained with reference to FIGS. 1 and 2A-E. FIGS. 2A-E are graphs schematically illustrating the bandwidth of the signals at various stages of the signal processing; the horizontal axis represents frequency.

FIG. 2A shows the spectrum 50 of the original signal S_{OR}, having a bandwidth BW_{OR}.

In the harmonic signal transfer path 20, the original signal S_{OR} is first filtered by a first filter 21 to produce a filtered original signal S1. The filtered original signal S1 contains only part of the signal components of the original signal S_{OR}. In FIG. 2B, this is illustrated by a spectrum 51 of filtered original signal S1 having a bandwidth BW1 which is clearly smaller than bandwidth BW_{OR} of the original signal S_{OR}.

The upper frequency limit of bandwidth BW1 may be substantially equal to the upper frequency limit 59 of bandwidth BW_{OR}; in that case, first filter 21 may be a high-pass filter having a predetermined cut-off frequency determining the lower frequency limit of bandwidth BW1. However, the upper frequency limit of bandwidth BW1 may also be lower than the upper frequency limit 59 of bandwidth BW_{OR}; in that case, first filter 21 may be a band-pass filter having a predetermined lower cut-off frequency determining the lower frequency limit of bandwidth BW1 and a predetermined upper cut-off frequency determining the upper frequency limit of bandwidth BW1.

Filter devices are known per se, and any suitable known per se filter device may be used to implement filter device 21, as will be clear to a person skilled in the art; therefore, no detailed description of the construction and functioning of such filter device is necessary here. For instance, first filter device 21 may be a (linear phase) IIR filter, or (linear phase) FIR filter, in a digital implementation. However, in an analog circuit, analog implementations are suitable, too. With respect to linear phase IIR filters, reference is made to the article “A technique for realizing linear phase IIR filters” by S. R. Powell and P. M. Chau in IEEE Trans. on Signal Processing, 39(11), 1991, pp. 2425-2435.

The filtered original signal S1 is processed by a processing device 22 in a nonlinear way, such that harmonic distortion is introduced in a controlled manner, and an output signal S2 of the processing device 22, having a spectrum 52 with a bandwidth BW2, contains frequency components with frequencies higher than the upper frequency limit of the frequency band of the filtered original signal S1, as illustrated by FIG. 2C.

The exact width, and positions, of the bandwidth limits of BW2 depend on the properties of the processing device 22. Generally, the frequency spectrum of the output signal S2 of the processing device 22 will extend from the lower frequency limit of BW1 to the highest possible frequency (i.e. the Nyquist frequency).

In the embodiment as shown, the output signal S2 of the processing device 22 is filtered by a second filter 23 to produce a filtered harmonic signal S3 having a spectrum 53 with a bandwidth BW3. The second filter 23 is designed such that the bandwidth BW3 of the filtered harmonic signal S3 meets certain predetermined requirements. For instance, in order not to affect the original signal S_{OR}, the lower frequency limit of bandwidth BW3 is preferably not lower than the upper frequency limit of bandwidth BW_{OR}. On the other hand, bandwidth BW3 preferably is closely adjacent to bandwidth BW_{OR}. Therefore, the lower frequency limit of bandwidth BW3 is preferably substantially equal to the upper frequency limit of bandwidth BW_{OR}.

In principle, the upper frequency limit of bandwidth BW3 may be freely chosen, depending on “taste”. Second filter 23 may be designed to cut-off frequency components that are not useable, or to shape the bandwidth BW3 to have a predetermined width, for instance the next octave above BW_{OR} or a width identical to the width of BW_{OR}. Preferably, second filter 23 is a band-pass filter having a predetermined lower cut-off frequency equal to the upper frequency limit of bandwidth BW_{OR} of expected input signals, and having a predetermined upper cut-off frequency determining the upper frequency limit of bandwidth BW3.

In principle, second filter 23 is not essential, because combining the original signal S_{OR} with signal S2 already constitutes an improvement of the original signal S_{OR}. However, second filter 23 influences the improvement, especially the way the improved signal is perceived by a listener. A human listener may find the improved signal more or less pleasant. According to experiments conducted by the inventors, the most pleasant effect is obtained if second filter 23 is arranged such that BW3 corresponds substantially to the first octave above BW_{OR}. Thus, in the preferred embodiment, the low-frequency limit of BW3 is substantially equal to two times the low-frequency limit of BW1, while the high-frequency limit of BW3 is substantially equal to two times the high-frequency limit of BW1.

It is noted that, in cases where the upper frequency limit of BW_{OR} is located one octave below the Nyquist frequency, BW2 will intrinsically correspond to the first octave above BW_{OR}, even without the presence of second filter 23.

As mentioned above with reference to first filter 21, any suitable known per se filter device may be used to implement second filter device 23, as will be clear to a person skilled in the art; therefore, no detailed description of the construction and functioning of such filter device is necessary here. For instance, second filter device 23 may be a (linear phase) IIR filter, or FIR filter, in a digital implementation. However, in an analog circuit, analog implementations are suitable, too.

The filtered harmonic signal S3 is amplified or attenuated by a suitable gain factor G, to produce signal S_{HAR}. The exact value of gain G needs to be determined in dependence of the circumstances, such that S_{HAR} suitably fits S_{OR}, i.e. that the overall spectrum of the output signal S_{OUT} is as smooth as possible, as will be clear to a person skilled in the art.

The non-linear processing device 22 can be implemented by various known per se devices. In principle, any device can be used if the device is of a type whose output signal comprises harmonic frequencies. Preferably, the device should have amplitude linearity. Suitable devices are, for instance: a full wave rectifier; a half wave rectifier; a half wave integrator; a full wave integrator; a level dependent clipper; a limiter. Depending on the choice of type, the non-linear processing device 22 generates even harmonics (e.g. in the case of a rectifier) or odd harmonics (e.g. in the case of a clipper).

With respect to full-wave integrators, reference is made to U.S. Pat. No. 6,111,960 to R. M. Aarts and S. P. Straetemans.

Further, the output signal S2 generated by the device should preferably have strong frequency components at two times the frequency of the input signal. This requirement is met by a full wave rectifier; a half wave rectifier; a half wave integrator; a full wave integrator. The harmonics generated by a rectifier are almost exclusively at the double frequency, whereas an integrator also generates frequency components at higher harmonics. Further, the computational complexity of a rectifier is less than the computational complexity of an integrator. Therefore, the non-linear processing device 22 is preferably implemented by a full wave rectifier or a half wave rectifier.

It is to be noted that the non-linear processing device 22 generates harmonic signals for each signal component of its input signal S1. Thus, if the lower frequency limit of BW1 is chosen too low, the harmonic signals generated on the basis of the low-frequency components of S1 will lie within BW_{OR}, which is not desired. Therefore, the lower cut-off frequency of first filter 21 is preferably chosen such that the generated harmonics all have frequencies higher than the upper frequency limit of BW_{OR}. Further, those signal components of the original signal S_{OR} having a frequency above the upper frequency limit of BW_{OR} will have very low amplitude, and will result in harmonic signals having also very low amplitude, such that they contribute very little or not at all to the extension of the bandwidth. Specifically, first filter 21 is preferably arranged such that BW1 corresponds substantially to the highest octave within BW_{OR}.

As will be known to persons skilled in the art, each filter characteristic shows a transition range from passband to stopband, corresponding to the filter order. A narrow transition range corresponds to a high filter order. Preferably, the filter orders of the lower cut-off frequency and of the higher cut-off frequency are each in the range of 3 to 6; higher filter orders are not necessary, yet increase computational complexity. This applies to first filter 21 as well as to second filter 23.

It is to be noted that the signal in the harmonic signal transfer path 20 experiences a delay. As a consequence, the harmonic signal S_{HAR} reaches combiner 30 somewhat later than the original signal S_{OR}. Nevertheless, combining the original signal S_{OR} with the delayed harmonic signal S_{HAR} already results in an output signal S_{OUT} that is improved with respect to the original signal S_{OR}. A further improvement can be achieved by incorporating the delay device 11, which is preferably arranged such that the delay experienced by the original signal S_{OR} in the original transfer path 10 is substantially equal to the delay experienced by the signal in the harmonic signal transfer path 20. A person skilled in the art will know how to calculate or measure desired delay and how to set delay device 11 accordingly.

### EXAMPLE 1

The following is an example for the case of an input signal S_{OR} having a spectrum in the frequency range 0-6 kHz (bandwidth BW_{OR}=6 kHz). Such frequency range may correspond to the frequency range for MP3 audio, either delivered as an internet radio signal or played in an MP3 player. Then, the first filter 21 may for instance have a passband from 3 to 6 kHz, and the second filter 23 may for instance have a passband from 6 to 12 kHz.

### EXAMPLE 2

The following is an example for the case of a digital signal, sampled at a sampling frequency of 11.025 kHz. The spectrum of this signal can reach to about 5 kHz, i.e. about half the sampling frequency. Such frequency range may correspond to the frequency range for MP3 audio, either delivered as an internet radio signal or played in an MP3 player. With the present invention it is possible to generate a digital signal having a spectrum with a higher upper limit. However, as is well-known, the sampling frequency should be at least twice the upper limit of the frequency spectrum. Therefore, before entering the branches 10 and 20, the original signal S_{OR} is firstly up-sampled, and then filtered by a low-pass filter to remove alias-components. If it is intended to generate a signal having a spectrum with a higher upper limit of about 11 kHz, the up-sampling should involve at least a factor 2. By up-sampling with a factor 2, the new version of the signal is sampled at a sampling frequency of 22.05 kHz, still having a spectrum up to 5 kHz.

After processing in the signal processing system 1 as described in the above, the output signal S_{OUT} will have a sampling frequency of 22.05 kHz and can have a spectrum up to 11 kHz.

In the above, the invention has been explained for the case where it is desired to broaden the spectrum of a signal. However, the present invention can also be applied to improve the content of a spectrum without necessarily broadening the spectrum, as will now be explained with reference to FIGS. 1 and 3A-E. An example of this situation is described in EXAMPLE 3.

FIG. 3A illustrates the spectrum of an original signal S_{OR}, the spectrum in general being indicated with reference numeral 60. The spectrum 60 has a lower frequency portion 61 and a higher frequency portion 62, having bandwidth BW61 and BW62, respectively. A transition point between lower frequency portion 61 and higher frequency portion 62 is indicated as 66. In the example as shown, spectrum portions 61 and 62 are adjacent, and complement each other with respect to the full spectrum 60. Further, in the example as shown, the bandwidth BW61 of lower frequency spectrum portion 61 is larger than the bandwidth BW62 of higher frequency spectrum portion 62.

Suppose one is not satisfied with the contents of higher frequency spectrum portion 62, indicated by a wavy and sloping top line in FIG. 3A. A well-known way of improving the higher frequency spectrum portion 62 involves a linear amplification of the signal components within the higher frequency spectrum portion 62. A disadvantage of this technique is, however, that noise components within the higher frequency spectrum portion 62 are amplified as well. According to the invention, the contents of higher frequency spectrum portion 62 can be enhanced without amplifying such noise components, by performing the processing steps of the invention on lower frequency spectrum portion 61. It is noted that lower frequency spectrum portion 61 generally contains less noise than higher frequency spectrum portion 62; therefore, the enhanced spectrum according to the invention will generally contain less noise as compared with equalization of higher frequency spectrum portion 62.

Thus, the first filter 21 is designed for passing an upper frequency portion 63 of lower frequency spectrum portion 61, as illustrated by FIG. 3B. Said upper frequency portion 63 of lower frequency spectrum portion 61 preferably corresponds to the highest octave below transition point 66. Non-linear device 22 produces a signal with a frequency spectrum 64 which embraces higher frequency spectrum portion 62, as illustrated by FIG. 3C, and the second filter 23 is designed for passing only frequencies in that spectrum portion 65 of frequency spectrum 64 which corresponds to higher frequency spectrum portion 62, as illustrated by FIG. 3D. Alternatively, the second filter 23 may be designed for passing only frequencies in that spectrum portion 65 of frequency spectrum 64 which corresponds to the first octave above transition point 66.

When the signal of non-linear device 22, after suitable amplification/attenuation, is combined with original signal S_{OR}, the resulting output signal still has a frequency spectrum corresponding to the original frequency spectrum of original signal S_{OR}, but the contents of the higher frequency spectrum portion 62 is enhanced, as illustrated by the straight line in FIG. 3E.

### EXAMPLE 3

In the case of CD audio, the digital signals have a spectrum from 0-22.05 kHz. Suppose that it is desired to enhance the spectrum in the range 11-22 kHz. This can be achieved for instance by designing first filter 21 as a band pass filter for the range 5.5-11 kHz and by designing second filter 23 as a band pass filter for the range 11-22 kHz.

Note that in this case, although involving digital signals, no up-sampling is required.

FIG. 4A illustrates schematically an embodiment of an apparatus 101 according to the invention. The apparatus 101 contains a signal processing device 1 as described above.

The figure shows a signal source 102, which may be an RF antenna, an SACD, a DVD, a CD, a CD-ROM with for instance MP3 files, a tape cassette, a vinyl record, or a device equipped for converting information from an information carrier to an optical or electrical signal. This list is, however, not limitative, as will be clear to a person skilled in the art. The figure also shows an output means, which may be a CD-burner, an electrical signal or an RF signal. However, also this list is not limitative, as will be clear to a person skilled in the art.

FIG. 4B illustrates schematically an embodiment of an information carrier 110 according to the invention. The information carrier 110 carries instructions which can be read and executed by a processor (not shown), the instructions being such as to enable said processor to perform the inventive signal processing method as described above.

In this embodiment as shown, the information carrier 110 is a diskette. However, the information carrier 110 may be of different type; for instance, the information carrier 110 may be implemented as a CD-ROM, a flash card, or a mass storage device coupled to a WAN such as the Internet. Still other types of information carriers are possible, too, as will be clear to a person skilled in the art, and fall within the scope of the present invention.

Thus, the present invention succeeds in improving the perception of an audio signal by enhancing and/or expanding the higher frequency portion of the signal spectrum. The present invention is suitable for application in all types of situations where a signal spectrum is bandwidth limited and/or has an unsatisfying content, for instance due to intentional and/or natural limitations of a transfer path or a recording medium. Specific examples where the invention is applicable are: Internet radio; MP3 compressed music; spoken book; fixed net telephone; mobile telephone; sound reproduction equipment in general (television, radio, tape, CD, etc.).

It will be clear to a person skilled in the art that the present invention is not limited to the examples discussed above, but that alternatives, amendments, modifications and variations are possible within the scope of the invention as defined in the accompanying claims.

For instance, the invention has been described for one signal. In the case of multi-channel signals, such as for instance stereo sound, the processing as described above is performed for each channel independently of the other channels.

Further, the invention is not limited to the filter characteristics as mentioned; other settings are possible, too. For example, second filter 23 may have a wider bandwidth BW3 than described.

Further, it is noted that the components of the inventive system can be implemented in analog components or in digital components, as desired. The components can be individual components, or integrated into one component. Also, the invention can be implemented as functional modules in software.

1. Method for processing a sound signal (S_{OR}), wherein harmonic signals (52; 64) are generated on the basis of at least a portion (51; 63) of the original signal (S_{OR}), and wherein at least a portion (53; 65) of said harmonic signals are combined with the original signal (S_{OR}).

2. Method according to claim 1, wherein said portion (53; 65) of said harmonic signals and said original signal (S_{OR}) are added.

3. Method according to claim 1 or 2, wherein said portion (53; 65) of said harmonic signals is attenuated or amplified before combination with the original signal (S_{OR}).

4. Method according to any of the previous claims, wherein the original signal (S_{OR}) is delayed before combination with said portion (53; 65) of said harmonic signals.

5. Method according to any of the previous claims, wherein said portion (51; 63) of the original signal (S_{OR}) corresponds to a frequency range of one octave.

6. Method according to claim 5, the original signal (S_{OR}) having a spectrum with an upper frequency limit, wherein said portion (51) of the original signal (S_{OR}) corresponds to the highest octave below said upper frequency limit.

7. Method according to claim 5, the original signal (S_{OR}) having a spectrum (60) with a lower frequency spectrum portion (61) and an adjacent higher frequency spectrum portion (62), wherein said portion (63) of the original signal (S_{OR}) corresponds to the highest octave within said lower frequency spectrum portion (61).

8. Method according to any of the previous claims, the original signal (S_{OR}) having a spectrum with an upper frequency limit, wherein said portion (53) of said harmonic signals is adjacent to the spectrum of said original signal (S_{OR}) at its upper frequency limit.

9. Method according to any of the previous claims, wherein said portion (53; 65) of said harmonic signals corresponds to a frequency range of one octave.

10. Method according to claim 9, the original signal (S_{OR}) having a spectrum with an upper frequency limit, wherein said portion (53) of said harmonic signals corresponds to the first octave above said upper frequency limit.

11. Method according to claim 9, the original signal (S_{OR}) having a spectrum (60) with a lower frequency spectrum portion (61) and an adjacent higher frequency spectrum portion (62), wherein said portion (65) of said harmonic signals corresponds to the first octave above said lower frequency spectrum portion (61).

12. Method according to any of the previous claims, wherein said harmonic signals are generated by a non-linear device.

13. Method according to claim 12, wherein said harmonic signals are generated by a half-wave rectifier or a full-wave rectifier; or a half-wave integrator or a full-wave integrator; or a clipper; or a limiter; wherein the half-wave rectifier or full-wave rectifier being most preferred.

14. Signal processing system (1), comprising:
an input (2) for receiving an original sound signal (S_{OR}), and an output (3) for providing an output signal (S_{OUT});
a combiner (30) having an output coupled to the output (3) of the system (1);
a first signal transfer path (10) between said input (2) and a first input of said combiner (30) for transferring the original signal (S_{OR});
a second signal transfer path (20) between said input (2) and a second input of said combiner (30);
wherein the second signal transfer path (20) comprises a processing device (22) arranged for generating a harmonic signal (S2) on the basis of the original sound signal (S_{OR}).

15. Signal processing system according to claim 14, wherein the combiner (30) comprises an adder.

16. Signal processing system according to claim 14 or 15, wherein said first signal transfer path (10) comprises a delay device (11).

17. Signal processing system according to claim 16, wherein the delay in the first signal transfer path (10) substantially matches the delay in the second signal transfer path (20).

18. Signal processing system according to any of claims 14-17, further comprising an attenuator or amplifier (24) in the signal path between processing device (22) and combiner (30).

19. Signal processing system according to any of claims 14-18, further comprising a first filter (21) in the second signal transfer path (20) between input (2) and processing device (22).

20. Signal processing system according to claim 19, wherein the first filter (21) is arranged for outputting a signal (S1) having a spectrum (51; 63) which is a portion of the spectrum (50; 60) of original signal (S_{OR}).

21. Signal processing system according to claim 20, wherein the spectrum (51; 63) of output signal (S1) of first filter (21) has a bandwidth (BW1) of approximately 1 octave below a first predetermined reference frequency (59; 66).

22. Signal processing system according to any of claims 14-21, further comprising a second filter (23) in the second signal transfer path (20) between processing device (22) and combiner (30).

23. Signal processing system according to claim 22, wherein the second filter (23) is arranged for outputting a signal (S3) having a spectrum (53; 65) which is a portion of the spectrum (52; 64) of the output signal (S2) of processing device (22).

24. Signal processing system according to claim 23, wherein the spectrum (53; 65) of output signal (S3) of second filter (23) has a bandwidth (BW3) of approximately 1 octave above a second predetermined reference frequency (59; 66).

25. Signal processing system according to claims 21 and 24, wherein said second predetermined reference frequency (59; 66) substantially coincides with said first predetermined reference frequency (59; 66).

26. Signal processing system according to any of claims 14-25, wherein the nonlinear processing device (22) is implemented by a full wave rectifier or a half wave rectifier.

27. Signal processing system according to any of claims 14-26, further comprising means for upsampling an input signal (S_{OR}), and further comprising low-pass filter means for filtering the upsampled input signal (S_{OR}).

28. Signal processing system according to any of claims 14-27, implemented as a suitably programmed processor.

29. Information carrier (110), carrying instructions which can be read and executed by a processor, the instructions being such as to enable said processor to perform the method according to any of claims 1-13.
